(19) United States
(12) Patent Application Publication
(10) Pub. No.: US 2013/0140074 A1
(43) Pub. Date: Jun. 6, 2013

(54) VIA HOLE PLATING METHOD AND PRINTED CIRCUIT BOARD MANUFACTURED USING THE SAME

(71) Applicant: SAMSUNG ELECTRO-MECHANICS CO., LTD., Gyeonggi-do (KR)

(72) Inventors: Jae Joon Yang, Gyeonggi-do (KR); Kwang Ok Jeong, Gyeonggi-do (KR); Hyo Seung Nam, Gyeonggi-do (KR)

(73) Assignee: SAMSUNG ELECTRO-MECHANICS CO., LTD., Gyeonggi-do (KR)

(21) Appl. No.: 13/692,996

(22) Filed: Dec. 3, 2012

(30) Foreign Application Priority Data
Dec. 5, 2011 (KR) 10-2011-0129137

(51) Int. Cl. H05K 1/11; H05K 3/00

(52) U.S. Cl. CPC H05K 1/115; H05K 3/0094
USPC 174/266; 29/852

(57) ABSTRACT

Disclosed herein is a via hole plating method including a first plating step of performing a pattern plating on a via hole of a printed circuit board; and a second plating step of performing a pattern fill plating on the pattern plating, whereby a deviation in plating thickness at a high current density region may be decreased simultaneously with improving a via filling efficiency, thereby making it possible to significantly improve the quality of the printed circuit board.

### CROSS REFERENCE(S) TO RELATED APPLICATIONS

This application claims the benefit under 35 U.S.C. Section 119 of Korean Patent Application Serial No. 10-2011-0129137, entitled “Via Hole Plating Method and Printed Circuit Board Manufactured Using the Same” filed on Dec. 5, 2011, which is hereby incorporated by reference in its entirety into this application.

### BACKGROUND OF THE INVENTION

1. Technical Field

The present invention relates to a printed circuit board, and more particularly, to a printed circuit board having a decreased deviation in plating thickness of a via hole and a via hole plating method thereof.

2. Description of the Related Art

In accordance with the recent continuous development in miniaturization and technology integration of electronic devices and products due to cutting edge electronic devices and products, a process of manufacturing a printed circuit board (PCB) used for the electronic device, or the like, has also required various changes, corresponding to the miniaturization and the technology integration.

The method of manufacturing the printed circuit board has progressed from an initial single sided printed circuit board to a double sided printed circuit board and has then progressed to a multilayered printed circuit board. Particularly, in manufacturing the multilayered printed circuit board, a manufacturing method referred to as so-called a build-up method has been performed.

Various via holes such as an inner via hole (IVH), a blind via hole (BVH), a plated through hole (PTH), or the like, are formed in order to electrically interconnect circuit patterns and electronic elements in each layer during manufacturing of the multilayered printed circuit board.

The via hole is completed by forming a via hole with a drill on the printed circuit board, performing a desmear process on a surface of the printed circuit board and an inner peripheral surface of the via hole and then filling an inner space of the via hole with a plating solution (via fill).

Here, since the filling of the via hole depends on efficiency of a pattern fill chemical product, a rapid deviation in plating thickness occurs due to resistance in a plating solution at a high current density area (about 1.4 ASD or higher).

In order to solve the above-mentioned problem, current density for plating may be decreased. However, since this case is required to change a plating time set in an equipment, it is impossible to be performed in an actual production.

In addition, in the case of simply performing a pattern fill plating twice, it is difficult to satisfy critical current density (1.0 ASD) for a via fill, such that a via filling efficiency may not be obtained at a desired level.

FIG. 1 is a cross-sectional view of a via hole formed by performing a pattern fill plating twice. As shown in FIG. 1, a pattern fill plating is first performed at a via hole 15 formed on a base substrate 12 to form a first plated layer 13, and the pattern fill plating is performed again to form a second plated layer 14.

Here, since the plating is performed by using low current in order to secure the deviation in plating thickness of the first plated layer 13, the critical current density is not sufficient at the second plated layer 14, such that the via hole is not completely filled but a dimple is generated.

### SUMMARY OF THE INVENTION

An object of the present invention is to provide a via hole plating method capable of decreasing a deviation in plating thickness of a via hole and via filling efficiency in a printed circuit board, and a printed circuit board manufactured using the same.

According to a first exemplary embodiment of the present invention, there is provided a via hole plating method including: a first plating step of performing a pattern plating on a via hole of a printed circuit board; and a second plating step of performing a pattern fill plating on the pattern plating.

The first plating step may include an electroless plating step of forming an electroless plated layer; and an electroplating step of forming an electroplated layer.

A plating solution having higher viscosity may be used in the second plating step than in the first plating step.

A plating solution containing less amount of sulfuric acid may be used in the second plating step than in the first plating step.

According to a second exemplary embodiment of the present invention, there is provided a printed circuit board including: a base substrate having a via hole formed therein; a first plated layer formed in the via hole by a pattern plating; and a second plated layer positioned on the first plated layer and formed by a pattern fill plating.

The first plated layer may include an electroless plated layer formed by an electroless plating; and an electroplated layer formed by an electroplating.

The second plated layer may be formed of a plating solution having higher viscosity than the first plated layer.

The second plated layer may be formed of a plating solution containing less amount of sulfuric acid than the first plated layer.

### BRIEF DESCRIPTION OF THE DRAWINGS

FIG. 1 is a cross-sectional view of a via hole formed by performing a pattern fill plating twice;

FIG. 2 is a cross-sectional view of a via hole formed by performing a via hole plating method of the present invention;

FIG. 3 is a graph showing process capability by a plating method according to the related art; and

FIG. 4 is a graph showing process capability by the via hole plating method according to the present invention.

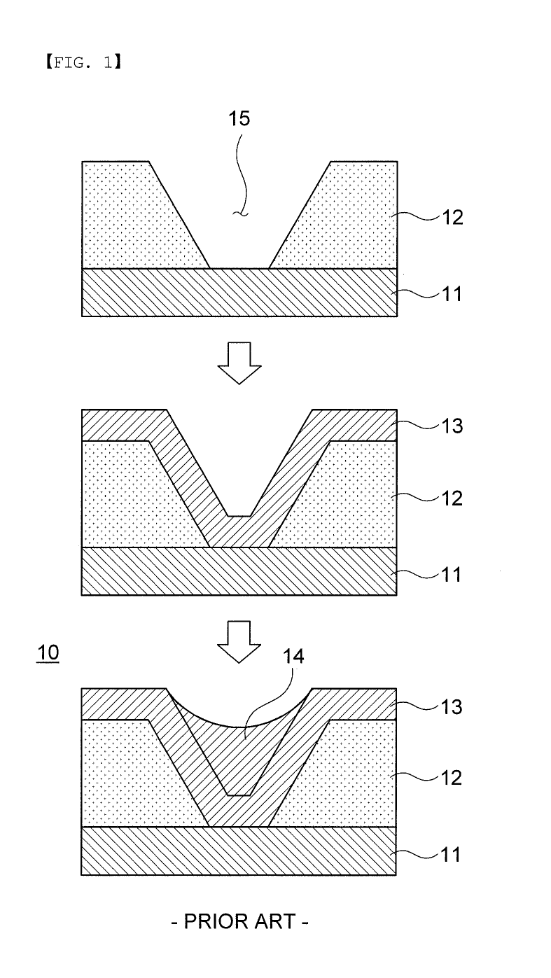

### DESCRIPTION OF THE PREFERRED EMBODIMENTS

Hereinafter, exemplary embodiments of the present invention will be described with reference to the accompanying drawings. However, the exemplary embodiments are described by way of examples only and the present invention is not limited thereto.

In describing the present invention, when a detailed description of a well-known technology relating to the present invention may unnecessarily make unclear the spirit of the present invention, a detailed description thereof will be omitted. Further, the following terminologies are defined in consideration of the functions in the present invention and may be construed in different ways by the intention of users and operators. Therefore, the definitions thereof should be construed based on the contents throughout the specification.

As a result, the spirit of the present invention is determined by the claims and the following exemplary embodiments may be provided to efficiently describe the spirit of the present invention to those skilled in the art.

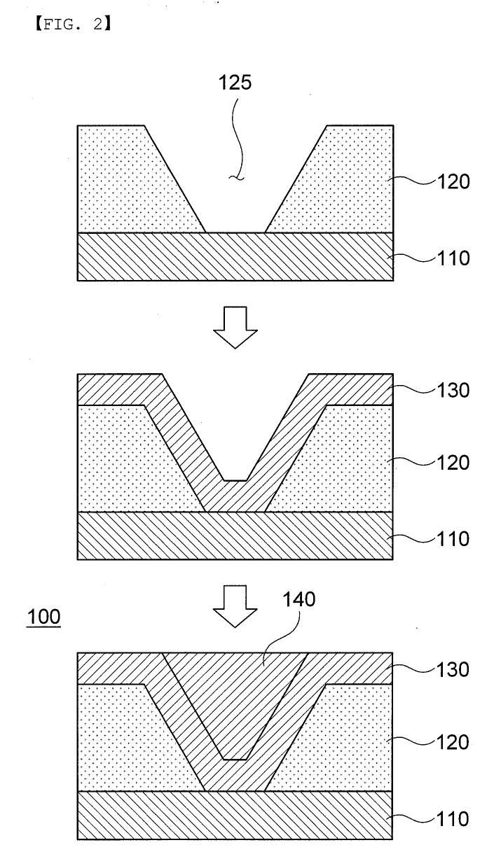

FIG. 2 is a cross-sectional view of a via hole formed by performing a via hole plating method of the present invention. Referring to FIG. 2, the via hole plating method of the present invention may include a first plating step and a second plating step.

First, when considering the forming process of a via hole 125, as a raw material of a base substrate 120 of a printed circuit board 100 having the via hole 125 formed therein, a copper clad laminate (CCL) and a glass fiber substrate impregnated in a thermosetting resin composition (a glass fiber reinforced prepreg impregnated in the thermosetting resin composition) may be used. Among them, the CCL includes a single sided copper clad laminate formed by sequentially stacking an insulating layer and a copper film, and a double sided copper clad laminate formed by sequentially stacking a lower copper film, an insulating layer, and a upper copper film.

In addition, the via hole 125, which is a plating through hole (PTH) penetrating through the base substrate 120, may be connected to a lower pattern 110, and be formed at a desired position on the substrate by drilling a reference hole using an X-ray drill or a sensor drill and then performing a drilling process with a computer numerical control (CNC) drill based on the reference hole.

Further, the via hole 125 may be formed by using an ultraviolet (UV) laser beam, a carbon dioxide (CO₂) laser beam, or the like. Here, the laser beam is not limited thereto. The via hole 125 may be formed by using various laser units.

Then, it is preferable to perform deburring and desmear processes that remove a variety of pollutants and foreign materials from the via hole 125 formed by the above-mentioned processes. The deburring process removes roughness of the copper clad generated during the drilling process, the dust particles on the inner wall of the via, the dust particles on the surface of the copper clad, the fingerprint, and the like, and provides roughness to the surface of the copper clad, thereby increasing adhesion of the copper in a subsequent plating process.

Meanwhile, a resin forming the substrate is melted due to heat generated during the drilling to be attached to the inner wall of the via. The desmear process is a process of removing the resin attached to the substrate. The melted resin attached to the inner wall of the via hole 125 serves as a decisive factor deteriorating quality of copper plating.

Meanwhile, the first plating step, which is a step of performing a pattern plating, is performed simultaneously with the pattern. In addition, the first plating step may include an electroless plating step of forming an electroless plated layer; and an electroplating step of forming an electroplated layer. More specifically, the first plating step is performed by performing an electroless copper plating such as a chemical copper plating and then performing an electric copper plating by using a deposited seed layer.

Since the pattern plating performed in the first plating step as described above has a small deviation in plating thickness, an inner size of the via hole 125 is decreased through the first plating step while securing the deviation in plating thickness, whereby the via hole 125 may be easily filled at a subsequent second plating step.

In the second plating step performed after the first plating step, a plating solution having higher viscosity than that in the first plating step may be used. Preferably, a plating solution containing less amount of sulfuric acid than that in the first plating step may be used. Here, the sulfuric acid is a material reducing solution resistance of the plating solution. Even with less amount of sulfuric acid contained in the second plating step, the size of the via hole 125 becomes small due to the first plating step, as compared to the first plating step, such that even though a larger amount of sulfuric acid is used than the case in which a pattern fill process and a via fill process are simultaneously performed, the via filling efficiency may be secured to thereby decrease the deviation in plating thickness.

Meanwhile, the printed circuit board 100 manufactured by the via hole plating method according to the present invention may include a base substrate 120, a first plated layer 130, and a second plated layer 140.

A via hole 125 connecting an upper layer to a lower layer of the substrate is formed on the base substrate 120. In addition, the first plated layer 130 may be formed through a pattern plating, and include an electroless plated layer formed by an electroless plating; and an electroplated layer formed by an electroplating.

As described above, the first plated layer is formed by performing the electroless copper plating such as a chemical copper plating and then performing the electric copper plating by using the deposited seed layer.

In addition, the second plated layer 140 may be positioned on the first plated layer 130, and be formed by using the plating solution having a viscosity higher than that of the first plated layer 130. Preferably, the second plated layer 140 may be formed by using the plating solution containing less amount of sulfuric acid than that in the first plated layer 130. The sulfuric acid is a material, which reduces solution resistance of the plating solution, allows the plating solution forming the second plated layer to have a viscosity higher than that of the plating solution forming the first plated layer, thereby making it possible to secure the via filling efficiency.

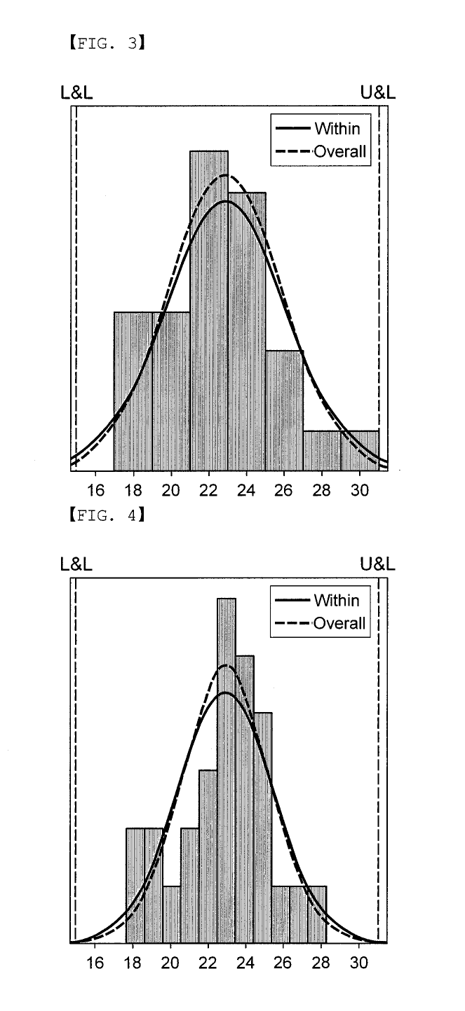

FIG. 3 is a graph showing process capability by a plating according to the related art, and FIG. 4 is a graph showing process capability by the via hole plating method according to the present invention.

When comparing the deviation in plating thickness by the via hole plating method of the related art and the deviation in plating thickness by the via hole plating method of the present invention with reference to FIGS. 3 and 4, in the case of performing the via hole plating method of the related art as shown in FIG. 3, a process capability index (Cpk) value of a deviation in plating thickness is 0.78.

However, in the case of performing the via hole plating method of the present invention as shown in FIG. 4, the Cpk value of a deviation in plating thickness is 1.14, such that it may be appreciated that the deviation in plating thickness in the case of the present invention may be decreased by about 30%, as compared to the case of the related art.

In FIGS. 3 and 4, lower limit (L&L) is 15, upper limit (U&L) is 31, and the number of samples is 23.

The via hole plating method and the printed circuit board manufactured using the same according to the present invention may decrease the deviation in plating thickness at the high current density region and the via filling efficiency, thereby making it possible to significantly improve the quality of the printed circuit board.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims.

Accordingly, the scope of the present invention is not construed as being limited to the described embodiments but is defined by the appended claims as well as equivalents thereto.

What is claimed is:

1. A via hole plating method comprising:
a first plating step of performing a pattern plating on a via hole of a printed circuit board; and
a second plating step of performing a pattern fill plating on the pattern plating.

2. The via hole plating method according to claim 1, wherein the first plating step includes:
an electroless plating step of forming an electroless plated layer; and
an electroplating step of forming an electroplated layer.

3. The via hole plating method according to claim 1, wherein a plating solution having higher viscosity is used in the second plating step than in the first plating step.

4. The via hole plating method according to claim 3, wherein a plating solution containing less amount of sulfuric acid is used in the second plating step than in the first plating step.

5. A printed circuit board comprising:
a base substrate having a via hole formed therein;
a first plated layer formed in the via hole by a pattern plating; and
a second plated layer positioned on the first plated layer and formed by a pattern fill plating.

6. The printed circuit board according to claim 5, wherein the first plated layer includes:
an electroless plated layer formed by an electroless plating; and
an electroplated layer formed by an electroplating.

7. The printed circuit board according to claim 5, wherein the second plated layer is formed of a plating solution having higher viscosity than the first plated layer.

8. The printed circuit board according to claim 7, wherein the second plated layer is formed of a plating solution containing less amount of sulfuric acid than the first plated layer.
